(19) United States
(12) Patent Application Publication
(10) Pub. No.: US 2006/0237723 A1
(43) Pub. Date: Oct. 26, 2006

(54) Semiconductor device and method of manufacturing the same

(75) Inventor: Katsuya Ito, Yokkaichi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/408,012

(22) Filed: Apr. 21, 2006

(30) Foreign Application Priority Data
Apr. 22, 2005 (JP) 2005-125190

(51) Int. Cl. H01L 29/04

(52) U.S. Cl. 257/59

(57) ABSTRACT

A semiconductor device includes a stopper film formed so as to cover an element formation region and an element isolation region, an interlayer insulating film formed on the stopper film, a contact hole formed in the element formation region so as to extend through the interlayer insulating film and the stopper film, and a contact plug buried in the contact hole. The contact hole includes an upper part extending through the interlayer insulating film, an intermediate part extending through the stopper film and a lower part formed by etching a surface of the element formation region. The lower part includes an interface between the intermediate part and the lower part and a part near to a central part. The interface has a first diameter and the part near to the central part has a second inner diameter. The lower part is formed so that the second diameter is larger than the first inner diameter.

### CROSS-REFERENCE TO RELATED APPLICATIONS

This application is based upon and claims the benefit of priority from the prior Japanese Patent Application No. 2005-125190, filed on Apr. 22, 2005, the entire contents of which are incorporated herein by reference.

### BACKGROUND OF THE INVENTION

1. Field of the Invention

The present invention relates to a semiconductor device formed with contact holes providing electric contact to a semiconductor substrate and a method of manufacturing the same.

2. Description of the Related Art

With progress of refinement in semiconductor devices composing an integrated circuit, suppression of contact resistance has become one of important problems to be overcome in forming contact holes connecting a wiring layer to a silicon substrate or to another wiring layer. This is because an area of contact hole tends to be reduced upon refinement of an element formation region. Accordingly, it has become difficult to reduce contact resistance structurally.

For example, JP-A-2000-349044 discloses a technique for overcoming structural increase in resistance with refinement of contact holes. In the disclosed technique, a part of the bottom of contact hole in contact with the semiconductor substrate is etched so that a lateral portion is formed in addition to the bottom, whereby a contact area is increased. In the disclosed technique, the increase in the contact area between the contact hole and the semiconductor substrate can be achieved by increasing the depth of the etching into the semiconductor substrate. However, damage to the semiconductor substrate becomes larger as the substrate is etched deeper.

### BRIEF SUMMARY OF THE INVENTION

Therefore, an object of the present invention is to provide a semiconductor device provided with a contact hole which can increase a contact area with the semiconductor substrate while an amount of etching into the element formation region can be rendered as small as possible.

In one aspect, the present invention provides a semiconductor device comprising a semiconductor substrate, an element formation region formed on the semiconductor substrate and defined by an element isolation region, a stopper film formed so as to cover the element formation region and the element isolation region, an interlayer insulating film formed on the stopper film, a contact hole formed in the element formation region so as to extend through the interlayer insulating film and the stopper film, and a contact plug buried in the contact hole. The contact hole includes an upper part extending through the interlayer insulating film, an intermediate part extending through the stopper film and a lower part formed by etching a surface of the element formation region. The lower part includes an interface between the intermediate part and the lower part and a part near to a central part thereof, the interface having a first diameter, the part near to the central part having a second inner diameter. The lower part is formed so that the second diameter is larger than the first inner diameter.

In another aspect, the invention provides a method of manufacturing a semiconductor device, which includes forming a stopper film and an interlayer insulating film on a semiconductor substrate having an element formation region defined by an element isolation region, forming a contact hole including an upper part extending through the interlayer insulating film, an intermediate part extending through the stopper film and a lower part formed by etching the element formation region, and burying a contact plug in the contact hole. The contact hole forming step comprises forming a through hole through the interlayer insulating film with the stopper film serving as a stopper, thereby forming the upper part of the contact hole, forming another through hole through the stopper film which is exposed as a result of formation of the through hole of the interlayer insulating film, thereby forming the intermediate part of the contact hole, etching the element isolation region exposed as a result of formation of the intermediate part, by an anisotropic etching process, thereby forming a cylindrical hole, and isotropically expanding an interior of the cylindrical hole by an isotropic etching process, thereby forming the lower part.

### BRIEF DESCRIPTION OF THE DRAWINGS

Other objects, features and advantages of the present invention will become clear upon reviewing the following description of the embodiment with reference to the accompanying drawings, in which:

FIG. 1 is schematic sectional view of a contact hole and its periphery in a semiconductor device in accordance with one embodiment of the present invention;

FIG. 2 is a schematic plan view of the contact hole and its periphery;

FIGS. 3A to 3D are schematic sectional views of the semiconductor device in sequential steps of the manufacturing process;

FIGS. 4A and 4B are schematic sectional views of a model for calculating an area of a contact face; and

FIGS. 5A and 5B are schematic illustrations indicative of hypothetical conditions for the calculation.

### DETAILED DESCRIPTION OF THE INVENTION

One embodiment of the invention will be described with reference to the accompanying drawings. The semiconductor device provided with a contact hole formed in accordance with the invention may be applied to various memory devices such as NAND or NOR flash memories, analog or logic circuits in each of which a contact hole is formed, and a contact hole formed to provided electrical contact to a semiconductor substrate.

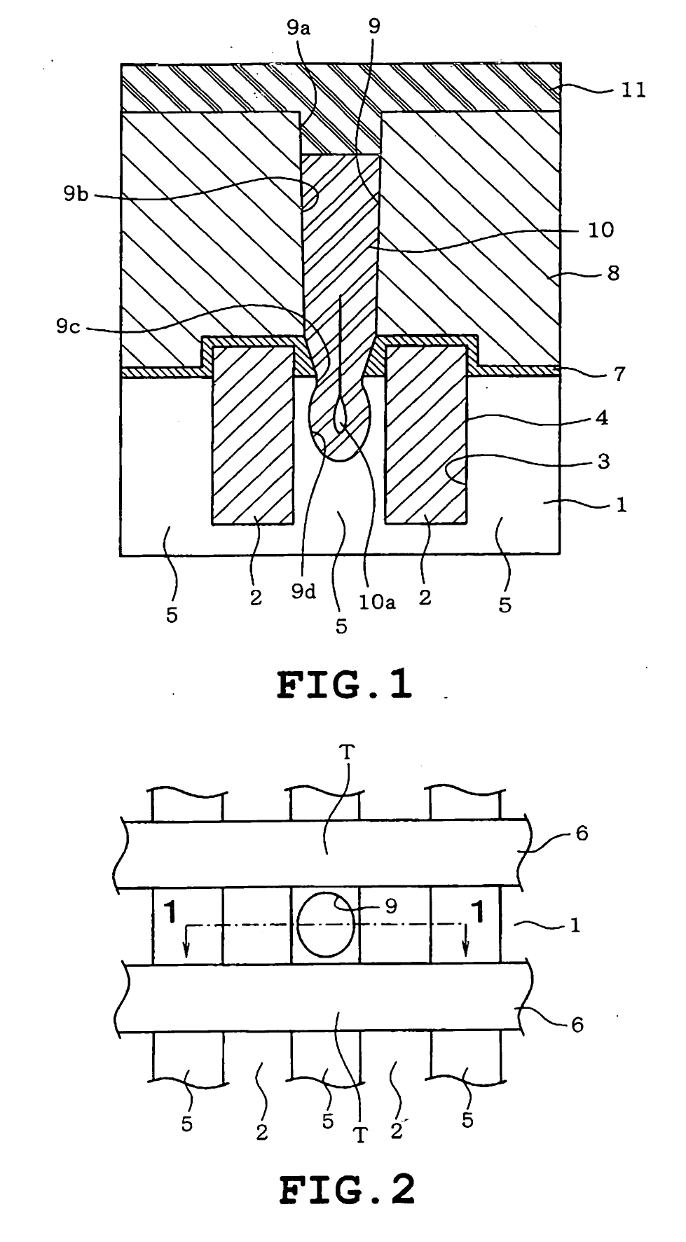

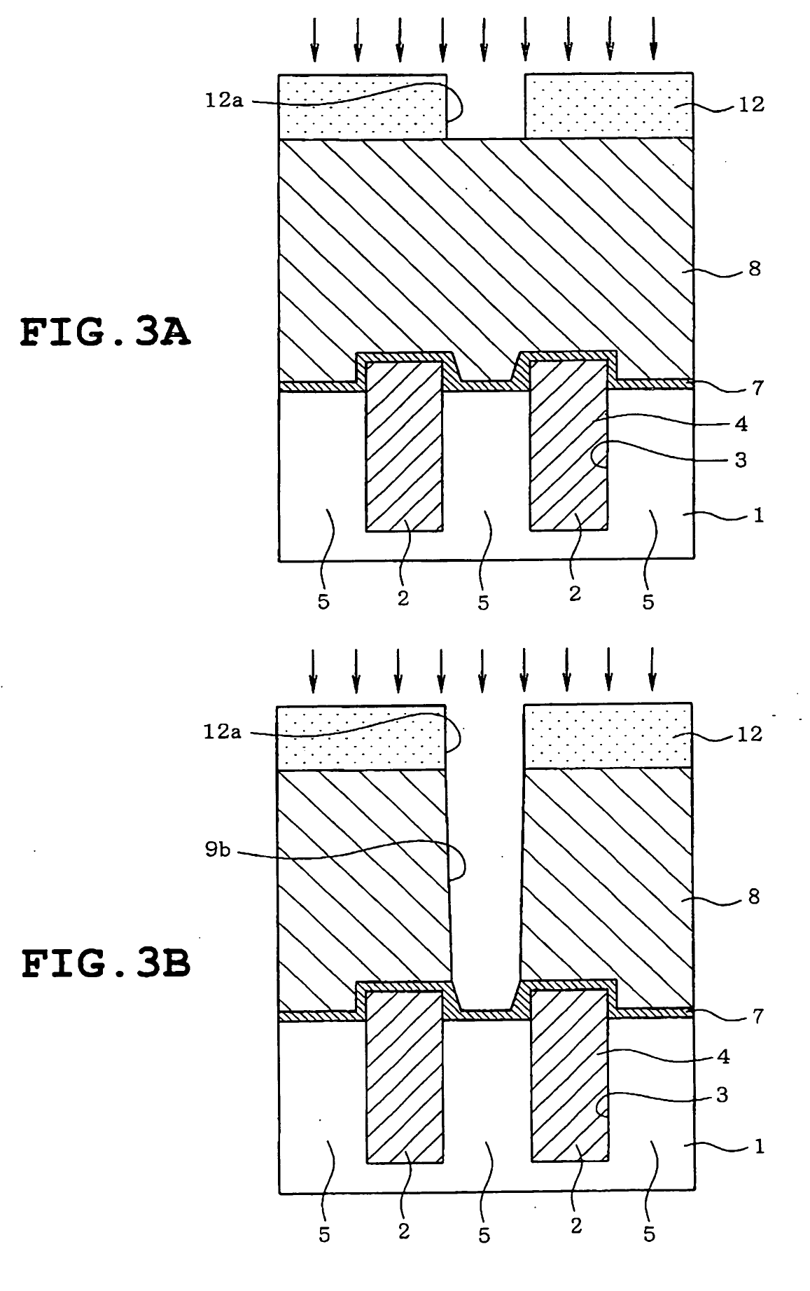

FIGS. 1 and 2 illustrate the structure of a contact hole and its periphery in a memory cell region of a memory device. Referring to FIG. 2, the memory device includes a memory cell region. The memory cell region includes isolation regions 2 formed by a shallow trench isolation (STI) method at predetermined intervals in a silicon substrate 1 serving as a semiconductor substrate. Each isolation region 2 serves as an element formation region 5. Gate electrodes 6 are formed so as to be perpendicular to the element formation regions 5 with gate insulating films interposed therebetween. A metal oxide semiconductor (MOS) transistor T serving as a memory device is formed at an intersection of the gate electrode 6 and the element formation region 5. An impurity diffusion region serving as a source/drain region is formed in portions of the element formation region 5 at both sides of the gate electrode 6. A contact hole 9 is formed in the impurity diffusion region. The contact hole 9 is circular or elliptic as viewed from above.

FIG. 1 is a sectional view taken along line 1-1 in FIG. 2 and shows a contact hole 9. Each isolation region 2 is formed by burying an insulating film 4 in a trench 3 formed in the silicon substrate 1. Each isolation region 2 has an upper surface located higher than an upper surface of the silicon substrate 1. A silicon nitride film 7 serving as a stopper film is formed on upper faces of the element formation region 5 of the silicon substrate 1 and each isolation region 2 located between adjacent gate electrodes 6. The silicon nitride film 7 functions as an etching stopper in the manufacturing process and has a film thickness of 20 nm, for example. An interlayer insulating film 8 is formed on the silicon nitride film 7 and has a film thickness of 700 nm, for example. The interlayer insulating film 8 may comprise a boro-phospho-silicate glass (BSPG) film, a tetraethyl orthosilicate (TEOS) film or a compound of these films.

A contact hole 9 is formed in the interlayer insulating film 8 on the element formation region 5 to provide electric conduction to the source/drain region of the silicon substrate 1. The contact hole 9 includes an upper part 9a having a peripheral wall comprised of the interlayer insulating film 8, an intermediate part 9b, having a peripheral wall comprised of the silicon nitride film 7 and a lower part 9c having a peripheral wall comprised of the silicon substrate 1. The upper part 9a has a lower end (an interface between the interlayer insulating film 8 and the silicon nitride film 7) with an inner diameter which is slightly smaller than an inner diameter of an upper end thereof. The peripheral wall of the interlayer insulating film 8 is slightly tapered rather than vertical.

Furthermore, the intermediate part 9b has a lower end (an interface between the silicon nitride film 7 and the silicon substrate 1) with a smaller inner diameter than an inner diameter of an upper end of thereof. The peripheral wall of the silicon nitride film 7 is formed so as to have a larger taper angle than a taper angle of the peripheral wall of the interlayer insulating film 8. The reasons for this formation is that the silicon nitride film 7 formed in a recess interposed between the isolation region 2 is formed so as to be thicker than the other part and further that the peripheral wall of the silicon nitride film 7 tends to be tapered in connection with etching conditions set in the stage of forming the contact hole 9. As a result, an inner diameter of an opening 9c of the contact hole 9 in contact with the silicon substrate 1 is rendered further smaller.

The lower part 9c, which is formed by etching the upper surface of the silicon substrate 1, includes a part which is near to a central part thereof and has a larger inner diameter than an inner diameter of an upper end (an interface between the interlayer insulating film B and the silicon nitride film 7) of the lower part 9c. The lower part 9c is formed so as to have an inner surface which has a vertically long elliptic spherical shape. As a result, the contact hole 9 has a laterally spread shape as compared with a contact face formed into a cylindrical shape obtained by etching the upper surface of the silicon substrate 1 with the size of the opening 9d being maintained, whereby an area of the contact face is effectively increased.

A contact plug 10 serving as an electrode is buried in the contact hole 9. A material for the contact plug 10 includes polycrystalline silicon, tungsten or the like. When tungsten is used, it is preferable to form a thin film of a barrier metal such as titanium nitride (TiN) on the contact face of the silicon substrate 1 and a tungstic contact plug on the barrier metal. The contact plug 10 is formed so that an upper surface thereof is located in the middle of the upper part 9a which is located lower by a predetermined distance from the upper end of the upper part 9a. The lower part 9c includes a lower part 9c including a part which is near to a central part thereof and has a larger inner diameter than an inner diameter of an upper end of the lower part 9c, as described above. Accordingly, a void 10a is formed in the lower part 9c. However, the void 10a would practically cause no trouble if the contact of the contact plug 10 with the silicon substrate 1 is good. A wiring layer 11 is formed on the upper surfaces of the interlayer insulating film 8 and contact plug 10. The wiring layer 11 is patterned so as to come into electrical contact with the contact plug 10.

Since the contact hole 9 is configured as described above, a contact area between the contact plug 10 and the silicon substrate 1 can be increased as compared with the conventional arrangement having the same depth as the contact hole 9, as will be described later. Consequently, an arrangement can be obtained which ensures an ohmic contact whose contact resistance is reduced according to a reduction in the area of the contact face with reduction in the design rules.

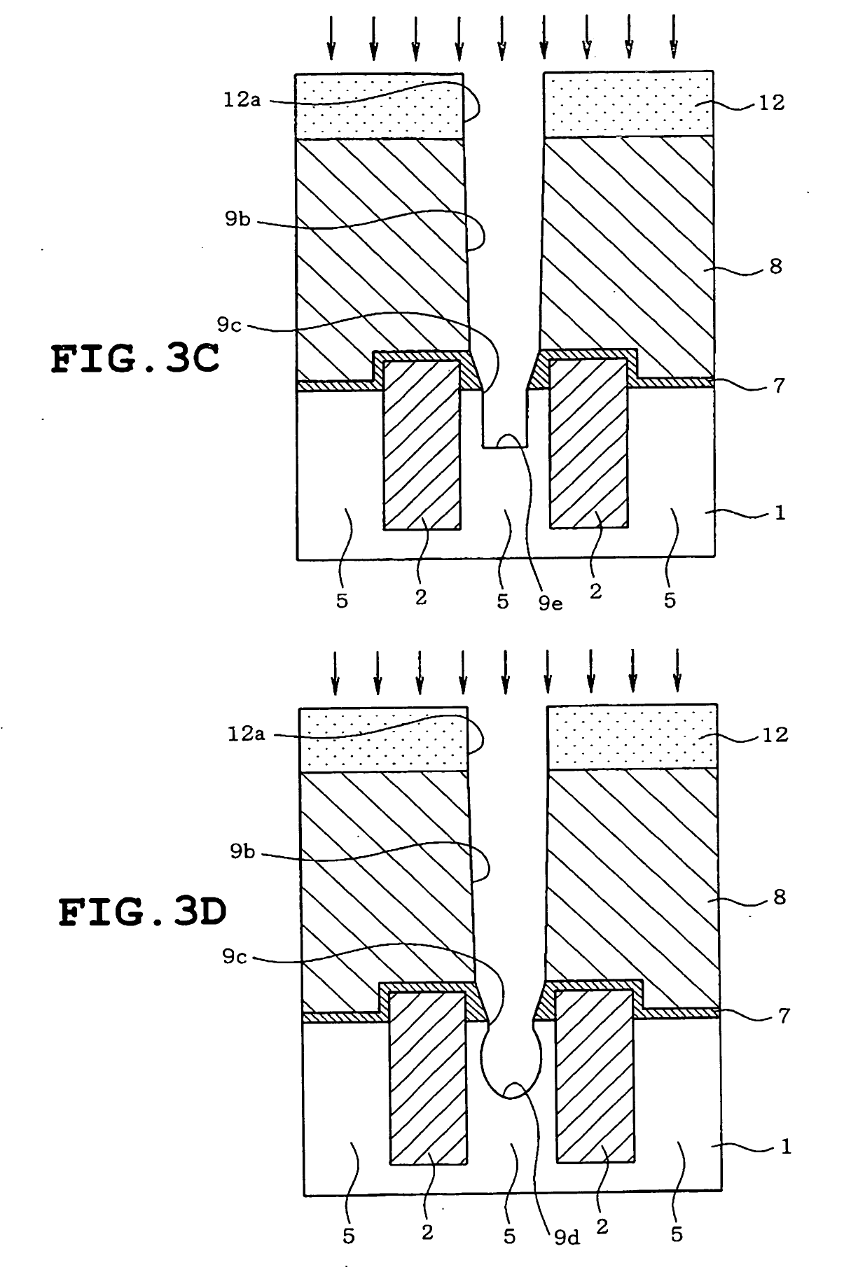

Next, major steps of the manufacturing process will now be described with reference to FIGS. 3A to 3D. Referring to FIG. 3A, the silicon nitride film 7 and the interlayer insulating film 8 are formed on the silicon substrate 1 into a multilayer. This state occurs before formation of the contact hole 9. In the shown arrangement, the isolation region 2 is formed at intervals of 100 nm, for example and has an upper surface protruding from the upper surface of the silicon substrate 1. Accordingly, an element formation region 5 defined between the isolation regions 2 is formed so as to be located lower than the upper surface of the isolation region 2.

The structure as shown in FIG. 3A is found in the process of forming a transistor of a memory cell region such as a NAND or NOR flash memory. In this structure, an area of the contact hole also tends to be reduced with reduction in the memory cell transistor.

The silicon nitride film 7 formed over the isolation regions 2 is formed into a narrow recess at a stepped portion between the silicon substrate 1 and the isolation region 2. Accordingly, the silicon nitride film 7 is formed into a tapered shape in which the silicon nitride film 7 is rendered thicker as the same approaches a boundary between the silicon substrate 1 and the same. The interlayer insulating film 8 is formed on the silicon nitride film 7. Before forming the interlayer insulating film 8, a step of forming the gate electrode 6 is carried out as described above. Thus, the interlayer insulating film 8 is formed after execution of these steps of forming the interlayer insulating film 8 and the gate electrode 6.

In the above-described state, a photolithography process is carried out so that a resist pattern 12 is formed on the interlayer insulating film 8 by patterning the photoresist film. The resist pattern 12 is provided for forming the contact hole 9 and has an opening 12a located above the element formation region 5.

Subsequently, as shown in FIG. 3B, the interlayer insulating film 8 is etched with the resist pattern 12 serving as a mask. In the embodiment, a reactive ion etching (RIE) process is carried out so that an anisotropic etching process is selectively executed for the silicon oxide film, whereby the upper part 9a of the contact hole 9 is formed. In the etching process, the silicon nitride film 7 functions as an etching stopper, whereupon the interlayer insulating film 8 can be etched under conditions uniform to the etching of the other contact holes 9 formed simultaneously.

Subsequently, as shown in FIG. 3C, the silicon nitride film 7 is etched by the RIE process and the silicon substrate 1 in the element formation region 5 is etched. In etching the silicon nitride film 7, the silicon nitride film 7 is tapered at the stepped portion of the isolation region 2. Accordingly, an opening 9d is formed which has a smaller diameter than a diameter of the lower end of the interlayer insulating film 8.

The step of etching the silicon nitride film 7 employs forming conditions that the resist pattern 12 is not retreated. Furthermore, a processing condition for the silicon nitride film 7 differs from a processing condition for the interlayer insulating film 8. In order that the silicon nitride film 7 may be prevented from being tapered and a contact area may be ensured, it is preferable to employ a condition of processing the silicon nitride film 7 vertically. However, when this condition is employed, the resist pattern 12 serving as a mask is retreated during processing of the silicon nitride film 7, whereupon the diameter of the upper opening of the contact hole 9 is increased. When the diameter of the upper opening of the contact hole 9 is increased, the wiring layer 11 formed over the contact hole 9 in a subsequent step tends to be short-circuited easily through the contact hole 9. Accordingly, a processing condition which does not retreat the resist pattern 12 is employed. Under this condition, the silicon nitride film 7 is given a taper angle whose value is smaller than 90° as shown in FIG. 3C. Consequently, an opening 9d of the contact hole 9 at the silicon substrate 1 side has a smaller area than in the case where the silicon nitride film 7 is processed vertically.

In the etching of he silicon substrate 1 in the element formation region 5, a hole 9e corresponding to the size of the opening 9d is formed. In this case, the silicon substrate 1 is etched so that the hole 9e has a depth shown by 1.5 R where R designates a diameter of the opening 9d. As a result, a cylindrical hole 9e is formed and accordingly, the contact area is increased as compared with the case where the upper surface of the silicon substrate 1 is just exposed.

The interior of the hole 9e is further etched by a chemical dry etching (CDE) process. In the embodiment, as shown in FIG. 3D, the inner wall of the hole 9e is isotropically etched by the CDE process so that the cylindrical inner surface is expanded into an elliptic shape, whereby the lower part 9c is formed. The CDE process has a processing condition that reactive radical to be used comprises gas plasma containing at least one of gases, CF₄, O₂, SF₆, CHF₃ and Cl₂.

In comparison of speeds at which the interlayer insulating film 8 of the upper hole 9a and the silicon substrate 1 are etched, the processing condition is set so that the speed at which the silicon substrate 1 is etched is sufficiently higher. Accordingly, the upper part 9a is prevented from being processed so as to have a curvature. Furthermore, since the processing condition is also set so that the etching speed of the silicon substrate 1 is sufficiently higher than an etching speed of the silicon nitride film 7, the silicon nitride film 7 is prevented from being retreated. Consequently, the etching is caused to progress only the part of the silicon substrate 1 in the etching by the CDE process such that the lower part can be processed as shown in FIG. 3D. As a result, since an elliptically spheric contact face is obtained, a larger contact area can be obtained as compared with an inner area of the aforementioned cylindrical hole 9e and accordingly, the contact resistance can be decreased.

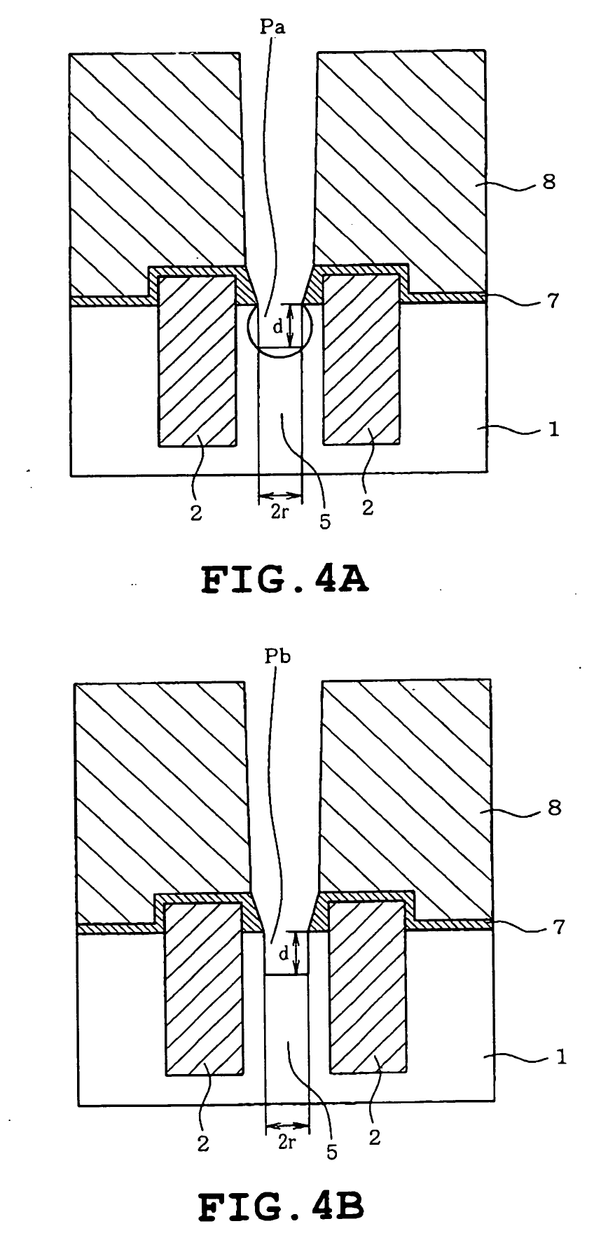

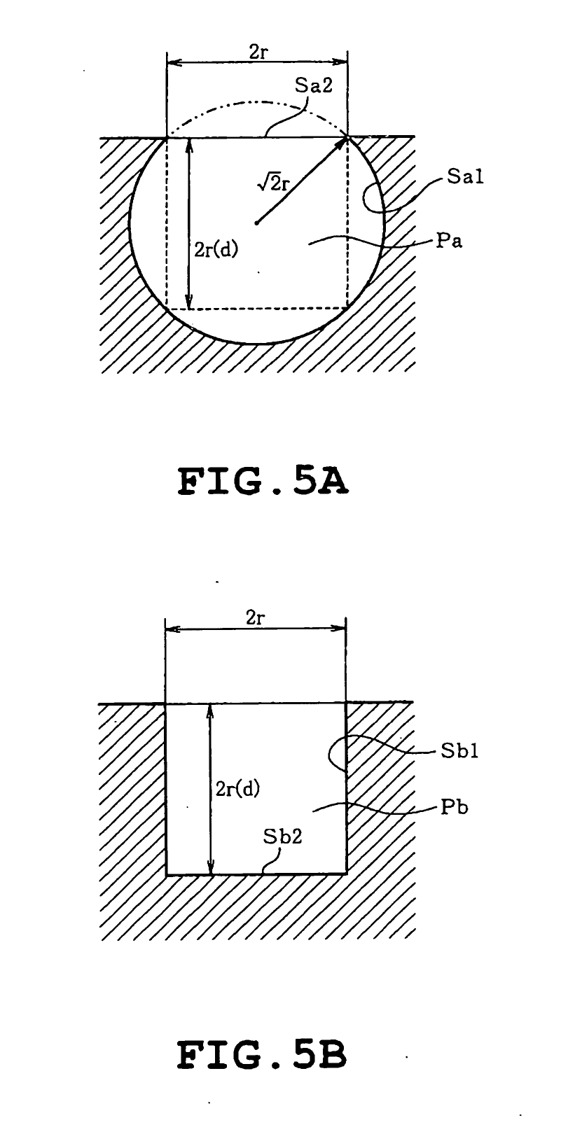

As described above, the silicon substrate 1 is etched at the lower end of the contact hole 9 so that an elliptically spheric lower part 9c is formed. Now, an approximated increase in the contact area will be described with reference to FIGS. 4A, 4B, 5A and 5B. Firstly, FIGS. 4A and 5A show the lower part Pa of the contact hole 9 in the embodiment, whereas FIGS. 4B and 5B show a part Pb of a conventional contact hole. It is assumed that the part Pb has a cylindrical opening formed into a circle with radius r and depth d equal to 2r as shown in FIGS. 4B and 5B. On the other hand, as shown in FIG. 5A, it is assumed that the lower part 9c of the contact hole 9 in the embodiment is formed into a sphere the corresponding part of the conventional contact hole touches internally, that is, a sphere with a radius √2-times larger than r, and the opening 9d has a radius r. The aforementioned estimation is a minimum relative to the area of the conventional contact face. Accordingly, since the embodiment in which the silicon substrate 1 is etched deeper than in the conventional case, the contact area tends to be increased and the contact resistance can further be decreased.

An area Sa of the contact face of the lower part 9c in FIG. 5A and an area Sb of the conventional contact face in FIG. 5B are calculated as follows. The area Sa is obtained by subtracting an area Sa2 of the circular opening 9c with radius r from the surface area Sa1 of a sphere with radius of √2×r as follows:

$$\begin{matrix}Sa = Sa 1 - Sa 2 \\ = 8 ⨯ ( π {r}^{2} ) - ( π {r}^{2} ) \\ = 7 ⨯ ( π {r}^{2} )\end{matrix} \qquad ( 1 )$$

Furthermore, an area Sb in the conventional arrangement is a sum of a side area Sb1 and bottom area Sb2 of a cylinder with radius r and height 2r:

$$\begin{matrix}Sb = Sb 1 + Sb 2 \\ = 4 ⨯ ( π {r}^{2} ) + ( π {r}^{2} ) \\ = 5 ⨯ ( π {r}^{2} )\end{matrix} \qquad ( 2 )$$

Accordingly, the area difference ΔS is obtained as follows:

$$\begin{matrix}Δ S = Sb - Sa \\ = ( 7 - 5 ) ⨯ ( π {r}^{2} ) \\ = 2 ⨯ ( π {r}^{2} )\end{matrix} \qquad ( 3 )$$

Thus, the surface area of the lower part 9c in the embodiment is at least twice as large as the area of the opening 9d as compared with the surface area of the cylindrical contact face in the conventional arrangement. Area difference ΔS obtained from equation (3) corresponds to an expected area increase in the case where the face Pb of the conventional contact hole contacting the silicon substrate is etched by depth r. In other words, the contact area can be increased without an excessive amount of etching.

The above-described estimation is based on the configurations as shown in FIGS. 4A and 4B but not on strict simulation. Accordingly, the estimation may not correspond with actual configurations but almost agrees with the actual configurations. Actually, however, when the lower part 9c is formed by the CDE process, the lower part 9c can be expected to be rendered further larger as a whole. Accordingly, since the contact area can further be increased, the effect of the device in the practical use thereof can be improved.

According to the embodiment, the contact hole 9 providing electrical contact with the silicon substrate 1 includes the upper part 9a extending through the interlayer insulating film 8 and the lower part 9c formed in the silicon substrate 1. The lower part 9c is etched by the CDE process into a laterally spread shape. Consequently, since the contact area is increased without an excessive amount of etching in the direction of the depth, the contact resistance can be decreased.

The invention should not be limited to the foregoing embodiment. The foregoing embodiment may be modified and expanded as described below. The invention may be applied to semiconductor devices in which contact is formed through the stopper film such as the silicon nitride film and the interlayer insulating film both formed on the semiconductor substrate.

Furthermore, the contact hole 9 is formed in the narrow element formation region 5 interposed between the isolation trenches 2 serving as the element isolation regions. However, the invention may be applied to any contact hole open to the silicon substrate 1 and can achieve the same effect as described above.

Furthermore, the silicon nitride film 7 formed on the silicon substrate 1 serves as the stopper film for the contact hole 9 in the foregoing embodiment. However, any other film serving as the stopper film may be employed, instead.

Furthermore, the intermediate part 9b and the lower part 9c are formed with the resist pattern 12 remaining. However, the resist pattern 12 may be delaminated when the upper part 9a is formed and the silicon nitride film 7 is exposed. Thereafter, the intermediate and lower parts 9b and 9c may be formed in turn.

Additionally, the CDE process is employed for formation of the lower part 9c in the foregoing embodiment. However, a wet etching process using alkaline chemical may be carried out, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate;
an element formation region formed on the semiconductor substrate and defined by an element isolation region;
a stopper film formed so as to cover the element formation region and the element isolation region;
an interlayer insulating film formed on the stopper film;
a contact hole formed in the element formation region so as to extend through the interlayer insulating film and the stopper film; and
a contact plug buried in the contact hole, wherein:
the contact hole includes an upper part extending through the interlayer insulating film, an intermediate part extending through the stopper film and a lower part formed by etching a surface of the element formation region;
the lower part includes an interface between the intermediate part and the lower part and a part near to a central part thereof, the interface having a first diameter, the part near to the central part having a second inner diameter; and
the lower part is formed so that the second diameter is larger than the first inner diameter.

2. The semiconductor device according to claim 1, wherein the lower part has an inner surface formed into a curved shape.

3. The semiconductor device according to claim 1, wherein the lower part is formed by etching the semiconductor substrate one and a half times as deep as the inner diameter of the interface or above.

4. The semiconductor device according to claim 2, wherein the lower part is formed by etching the semiconductor substrate one and a half times as deep as the inner diameter of the interface or above.

5. A method of manufacturing a semiconductor device, which includes forming a stopper film and an interlayer insulating film on a semiconductor substrate having an element formation region defined by an element isolation region, forming a contact hole including an upper part extending through the interlayer insulating film, an intermediate part extending through the stopper film and a lower part formed by etching the element formation region, and burying a contact plug in the contact hole, wherein the contact hole forming step comprises:
forming a through hole through the interlayer insulating film with the stopper film serving as a stopper, thereby forming the upper part of the contact hole;
forming another through hole through the stopper film which is exposed as a result of formation of the through hole of the interlayer insulating film, thereby forming the intermediate part of the contact hole;
etching the element isolation region exposed as a result of formation of the intermediate part, by an anisotropic etching process, thereby forming a cylindrical hole; and
isotropically expanding an interior of the cylindrical hole by an isotropic etching process, thereby forming the lower part.

6. The method according to claim 5, wherein in the step of forming the circular hole, an etching process is carried out by a reactive ion etching (RIE) process and in the step of forming the lower part, an etching process is carried out by a chemical dry etching (CDE) process or a wet etching process.
